(19) United States
(12) Patent Application Publication
(10) Pub. No.: US 2024/0039061 A1
(43) Pub. Date: Feb. 1, 2024

(54) SMART BATTERY

(71) Applicant: Iontra Inc, Centennial, CO (US)

(72) Inventors: John Richard HOWLETT, III, Centennial, CO (US); Manoj K. KOUL, Allen, TX (US); Daniel A. KONOPKA, Denver, CO (US)

(21) Appl. No.: 18/225,274

(22) Filed: Jul. 24, 2023

Related U.S. Application Data
(60) Provisional application No. 63/392,398, filed on Jul. 26, 2022.

(51) Int. Cl. H01M 10/42; H01M 10/48; G01R 31/36

(52) U.S. Cl. CPC H01M 10/4257; H01M 10/482; G01R 31/3648

(57) ABSTRACT

Aspects of the present disclosure involve a smart battery for mobile devices, or otherwise, that incorporate a more sophisticated charge (and in some instances discharge) techniques that provide an integrated intelligence, which may involve processing capability and/or memory, to facilitate sophisticated and more effective charging techniques as compared to other charging schemes. The benefits of such charging techniques include faster charging rates, slower battery degradation, enhanced capacity, enhanced capacity maintenance, improved temperature operation, and/or others. Moreover, the integrated intelligence may facilitate the adaptation of new battery arrangements for a mobile device where conventionally a mobile device can only operate with the battery to which it was designed, leaving no option for upgrading battery technology. In one implementation, a smart battery module is provided with some form of integrated intelligence in which functional units of a charging circuit are positioned between the mobile device and the battery unit itself.

### CROSS-REFERENCE TO RELATED APPLICATION

This application is related to and claims priority under 35 U.S.C. § 119(e) from U.S. patent application Ser. No. 63/392,398, filed Jul. 26, 2022, titled “Smart Battery,” the entire contents of which is incorporated herein by reference for all purposes.

### TECHNICAL FIELD

Embodiments of the present invention generally relate to systems and methods for charging or discharging a battery, and more specifically to a mobile system employing a battery module with integrated intelligence for operating sophisticated battery charging techniques.

### BACKGROUND AND INTRODUCTION

Battery powered mobile devices ranging from cell phones to power tools typically have some form of conventional charging arrangement where a battery in the device is charged by way of external power conditioning component. Such charging is typically done by way of constant current, constant voltage (CCCV) schemes. Under CCCV schemes, the battery is charged with a constant DC current and as the battery voltage increases toward the end of charge, the voltage is then held constant by reducing the current until a lower current limit is reached signaling the end of charge. An external device with power conditioning circuitry, typically in a housing with a connection to a wall outlet and a power cord with an appropriate power plug for the device, provides the power for the charge current to the battery in the mobile device. The charging methodology is typically relatively simple needing only to monitor voltage and control current.

It is with these observations in mind, among others, that aspects of the present disclosure were conceived.

### SUMMARY

One aspect of the present disclosure relates to a system comprising a computing device and a battery module in communication with the computing device and providing a power signal to the computing device. The battery module comprises a battery and a processing configuration to charge the battery consistent with a battery charging control instructions, wherein the battery charging control instructions cause a switching circuit of the computing device comprising at least one switch and at least one inductor operably coupled with the at least one switch to generate a charge signal for charging the battery, wherein the generated charge signal includes at least one harmonically tuned aspect.

Another aspect of the present disclosure relates to a method of charging an electrochemical device. The method includes the operation of determining, by a processing device of a battery module, a charge signal to charge a battery of the battery module, the battery module in communication with a computing device separate from the battery module and providing, by the battery, a power signal to power the computing device and transmitting the battery charging control instructions to a switching circuit of a computing device, the switching circuit comprising at least one switch and at least one inductor operably coupled with the at least one switch, the battery charging control instructions causing the switching circuit to generate the charge signal to charge the battery of the battery module, wherein the generated charge signal includes at least one harmonically tuned aspect.

Yet another aspect of the present disclosure relates to a battery module comprising a battery housing comprising a battery and a processing configuration to charge the battery consistent with battery charging control instructions generating a charge signal through control of a switching circuit comprising at least one switch and at least one inductor operably coupled with the at least one switch, wherein the generated charge signal includes at least one harmonically tuned aspect.

### BRIEF DESCRIPTION OF THE DRAWINGS

FIG. 1 is an illustration of a first example of a mobile device powered by a smart battery module in accordance with some embodiments.

FIG. 2 is an illustration of a second example of a mobile device powered by a smart battery module in accordance with some embodiments.

FIG. 3 is an illustration of a third example of a mobile device powered by a smart battery module in accordance with some embodiments.

FIG. 4A is a schematic diagram illustrating a circuit for power conversion utilizing a buck switching unit in accordance with some embodiments.

FIG. 4B is a schematic diagram illustrating a circuit for power conversion utilizing two FETS connected in a “back-to-back” configuration in accordance with some embodiments.

FIG. 5A is a signal diagram of a sequence of shaped charge signals generated from a battery charge circuit in accordance with some embodiments.

FIG. 5B is a signal diagram of a sequence of shaped charge signals generated from a battery charge circuit in accordance with some embodiment, the shaped charge signals including shaped leading edges with linear segments collectively approximating a non-linear shaped leading edge.

FIG. 6 is an illustration of a first smart battery arrangement with memory authentication module in accordance with some embodiments.

FIG. 7 is an illustration of a second smart battery arrangement with memory authentication module in accordance with some embodiments.

FIG. 8 is a diagram illustrating an example of a computing system which may be used in implementing embodiments of the present disclosure.

### DETAILED DESCRIPTION

Aspects of the present disclosure involve a smart battery for battery-powered devices, such as mobile phones, power tools and a myriad of other battery-powered device, where more sophisticated charge (and in some instances discharge) techniques are deployed and would benefit from a battery including integrated intelligence, which may involve processing capability and/or memory, to facilitate sophisticated and more effective charging techniques as compared to CCCV schemes. The benefits of such charging techniques include faster charging rates, slower battery degradation, enhanced capacity, enhanced capacity maintenance, improved temperature operation, and/or others. Moreover, the integrated intelligence may facilitate the adaptation of new battery arrangements for battery-powered devices where conventionally such devices can only operate with the battery for which it was designed, leaving no option for upgrading battery technology. These and other advantages will be understood from the discussion that follows.

Various possible smart battery configurations are presented. Consistent with each possible configuration are various functional units. One difference between the various embodiments involves where those functional units are positioned between the mobile battery-powered device, which is discussed in some embodiments as a mobile phone but may be any number of different forms of devices powered by a rechargeable battery, and the battery unit itself—sometimes referred to herein as a smart battery. As noted, aspects of the smart battery module discussed herein involve a battery with some form of integrated intelligence.

The term “battery” in the art and herein can be used in various ways and may refer to an individual cell having an anode and cathode separated by an electrolyte as well as a collection of such cells connected in various arrangements. Further, the terms charging and recharging are used synonymously herein. A battery or battery cell is a form of electrochemical device. Batteries generally comprise repeating units of sources of a countercharge and first electrode layers separated by an ionically conductive barrier, often a liquid or polymer membrane saturated with an electrolyte but may also be a solid electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead acid batteries, various types of nickel batteries, and solid-state batteries, to name a few. The various implementations discussed herein may also apply to different structural battery arrangements such as cylindrical cells, pouch cells, and prismatic cells.

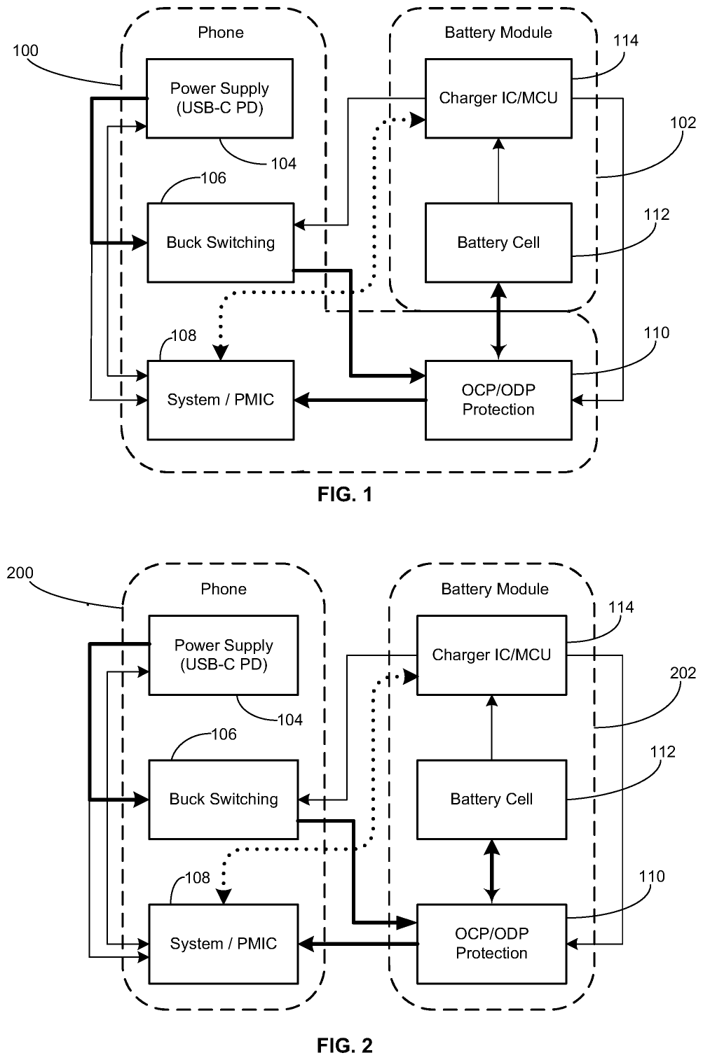

Referring first to FIG. 1, a device 100 powered by a smart battery module 102 is illustrated in a charging/recharging configuration. In one example, the device is a mobile phone or tablet, but other devices powered by a rechargeable battery are also contemplated. The device 100 includes a power supply unit 104 (e.g., a USB-C power delivery unit) for providing power to the device, a buck switching unit 106, system and power management units 108, and an over charge/over discharge protection unit 110. The battery module 102 includes a battery 112 and a processing device and/or a battery measurement unit 114, which may be provided on an integrated circuit with a microcontroller and voltage and current sensors in some implementations. The battery module may be a stand-alone device, which may include some form of housing, with the battery 112 and the processing device 114. As noted below, the processing device 114 may include some form of processing unit and/or computer memory.

As will be recognized from the discussion that follows, various operational units are consistent with various arrangements. In one example, the power supply 104 of the device 100 is operably coupled with a buck switching circuit 106. Conventional mobile devices typically include a power supply, which may be any form of standard power supply such as those conforming to universal serial bus (USB) standard, such as USB-C and USB-C PD, and any other possible form of power supply. Other forms of power supplies are also possible, such as a wireless Qi style charger. The power supply 104, such as in some possible implementations in which the voltage/current from the power supply is conditioned, may be coupled with a buck converter 106 to step down the voltage from the power supply and to possibly also regulate the current available for charging.

While a buck converter is discussed herein, it is also possible that a boost or buck/boost, or other form of power conversion is present. Referring to the example of a buck converter 106, the present system may involve a dedicated buck converter or may take advantage of a conventional buck converter of the device 100 which may also be used for other purposes and for charging in accordance with the discussion herein.

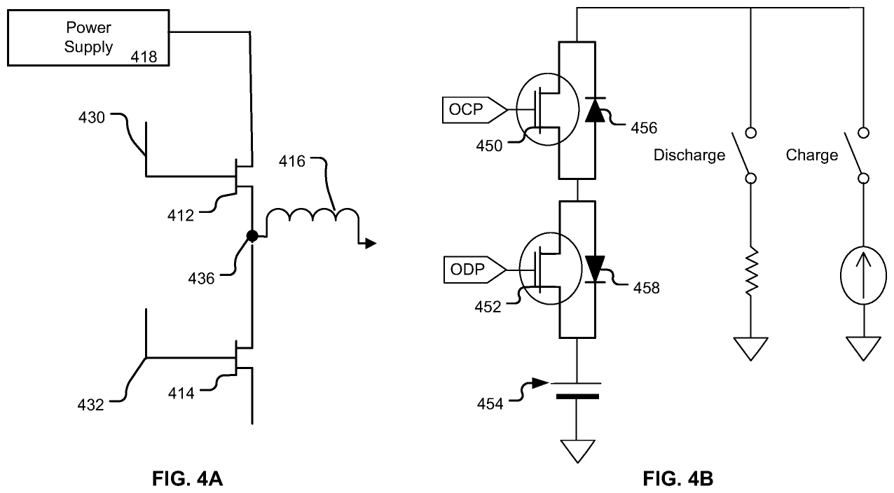

While various possible power conversion topologies are possible, in one example referring to FIG. 4A, the buck switching unit 106 comprises a switch operably coupled between the power supply 418 and an inductor 416. In the example illustrated, the buck configuration includes a first, upper transistor 412 and a second, lower transistor 414. In general, the transistors 412, 414 may be any type of transistor, e.g., a FET or more particularly a MOSFET, a GaN FET, Silicon Carbide based FETs, or any type of controllable switching element. The first switching element 412 is connected to a power rail and thereby connected to the power supply 418 (e.g., power supply 104) during charging. A drain of the first transistor 412 is coupled with a source of the second transistor at node 436. The gates of the respective transistors 412, 414 include control lines 430 and 432. In an alternative arrangement, the second, lower transistor 414 may be substituted with a diode or capacitor or other element. As such, in some implementations, only an upper, first transistor 412 is included in the buck circuit. In still other arrangements, the upper first transistor 412 may be substituted with another element such that only the lower transistor 414 is included, such as in a boost converter circuit. Through controlled pulse width modulated (PWM) signals to the gate or respective gates via control lines 430 and 432 (e.g., PWM signals generated by the Charger IC/MCU 114 of FIG. 1), the system may define a sequence of pulses at node 436 that are applied to the inductor 416, which alone or in combination with other elements, may shape a charge signal applied to the battery (e.g., battery 112 of FIG. 1).

In the examples of FIGS. 1-3, a battery module (102, 202, 302) includes a battery 112 and a processor 114. The processor may be a microcontroller unit (MCU). In one example, the MCU 114 is provided in an integrated circuit (IC). Being integrated with the battery module, the MCU 114 is preloaded or preconfigured with battery specific charging algorithms. The IC 114 may also include battery sensing to obtain battery voltage and/or current to the battery. The charging algorithm of the MCU 114 may be present in computer executable instructions or otherwise is configured to, based on the measured battery voltage and current, generate a shaped charging signal for the specific battery type of the module. The charging algorithm may also account for temperature and battery age.

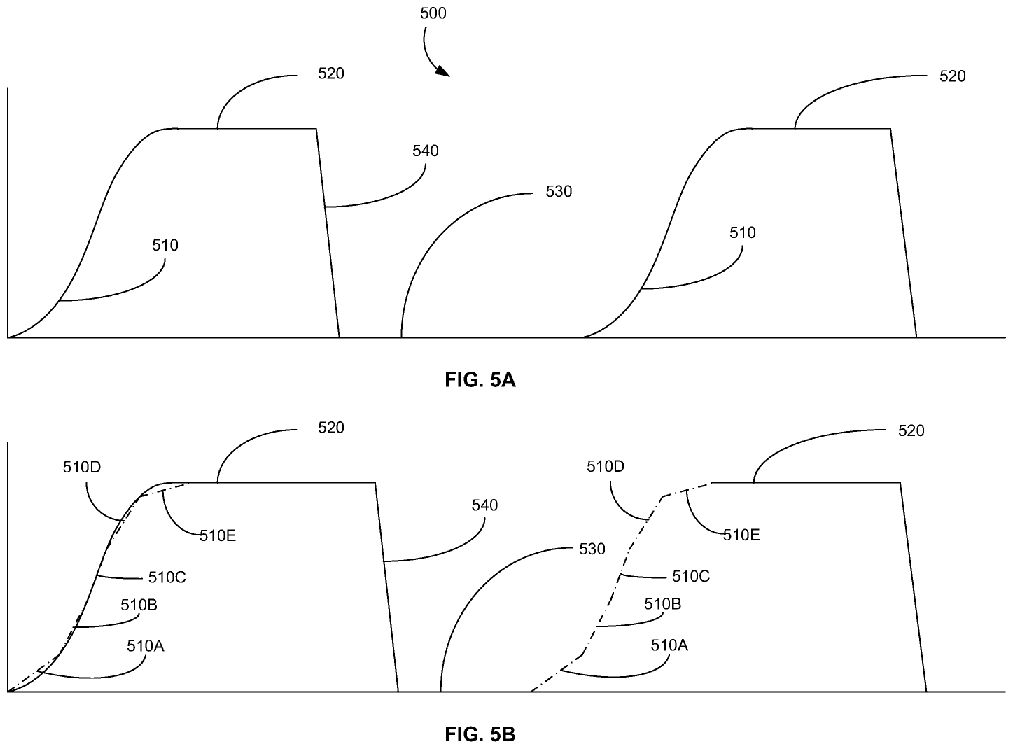

In various aspects and referring now to FIG. 5A, a charge signal 500 defined by the charging algorithm running on the MCU 114 may include a shaped leading edge 510, a body portion 520 and a rest portion 530. In one implementation, the shape of the leading edge 510 may be that of a sinusoid (portion thereof) at a frequency selected based on battery characteristics, such as a relatively low impedance harmonic frequency, minimal plating, combinations thereof, or otherwise. Moreover, for a variety of reasons, the frequency component or components of the charge signal may not correspond with the lowest frequency. For example, in the case of shaping a leading edge 510, such shaped leading edge may not correspond to the targeted frequency due to timing, shaping circuit employed, etc. In some instances, other factors such as energy transfer, temperature, and other issues may play a role in selecting harmonics to include or exclude from a charge signal and may dictate that a harmonic other than the harmonic associated with lowest impedance be utilized. Further, the frequency components of the charge signals may be set at a minimum impedance or near the minimum impedance, either above or below or both, depending on the implementation. Hence, it is not necessary that the frequency be set strictly at the minimum impedance.

In other implementations, the leading edge 510 may comprise a piecewise linear approximation to the selected frequency based on battery characteristics, such as a relatively low impedance harmonic frequency, minimal plating, combinations thereof, or otherwise. The shaped leading edge 510 is followed by a relatively steady charge current (e.g., the body portion 520) terminating at a falling edge 540. While not illustrated, in some embodiments the falling edge 540 may be followed by a heating portion, which may be a part of the rest period 530 or may be incorporated into the rest period. In some examples, the heating portion is a sinusoid or an approximation thereof. The sinusoid or other non-square pulse portion may include a negative portion (negative, reverse polarity, voltage) and a positive portion (positive voltage). The sinusoid may also ride on a non-zero DC offset such that there is no negative going portion. However, in the example of a FIGS. 5A and 5B, the body portion 520 is followed by a rest period 530. The rest period 530 may be zero current or may be some non-zero DC current less than the substantially DC current of the body portion 520. The peak current of the body portion 520 may be in the range of the battery specification's maximum rated current to multiples of that maximum rated current, depending on the type of cell with the rest current in the range of OA to the maximum rated current. In a specific example, the peak current of the body portion 520 may be in the range of 10 A to 60 A depending on the type of cell with the rest current in the range of 0 A to 10 A. Values for peak current, rest current, and other values may vary, as noted elsewhere herein, depending on temperature, the type of cell, circuit capabilities, state of charge, and other battery-related factors. In this example, if non-zero, the rest current may be less than a specified charge current if referencing conventional CCCV charging parameters.

It should be noted that the charge signal may or may not include a rest period. The leading edge may be in the form of about the first 90 degrees of sinusoid or may otherwise be shaped approximately of the shape of such a sinusoidal portion. Further, as noted and as illustrated in FIG. 5B, the shaped leading edge may be formed of linear segments, the collection of which approximate sinusoidal the leading edge 510. In such an arrangement, a first linear segment 510A increases voltage relatively slowly as compared to a square pulse, for example, where there is an immediate sharp increase in voltage, about 90 degrees. The following linear segments 510B-510E are linear approximations of the shaped-leading edge, which is included/retained in the first charge signal period for comparison and not-included in the second charge signal period. For comparison purposes, the rest period 530 of FIG. 5B is relatively shorter than the rest period of FIG. 5A. The overall charge period of the two charge signals comprising both the leading edge 510 period and the body 520 period is also relatively longer in FIG. 5B as compared to FIG. 5A, again for comparison. The buck or boost circuit may generate such linear approximations.

Referring back to FIGS. 1-4A, the charge algorithm of charger IC/MCU 114 may send control signals to the buck switching unit 106 to generate a sequence of pulses at node 236 to generate such a charging signal. As can be seen, while the system can produce a charge signal that would appear like a constant current, constant voltage type signal, the system is particularly arranged to generate a shaped charging signal, one example of which is shown and discussed with reference to FIG. 5, and which is not such a CCCV type signal.

In one example, the charging signal output of the buck unit 106, e.g., signal at inductor 416, is routed through an OCP/ODP protection circuit 110. OCP is over-charge protection and ODP is over-discharge protection. In many instances, over-charge and over-discharge protection may be provided, which protection essentially prevents over charging or over discharging a battery. Over-charge is typically defined based on a battery voltage that cannot be exceeded during charge and over-discharge is typically defined as a lower battery voltage that the battery is prevented from discharging below. So long as the battery voltage is between the upper and lower threshold, the battery may either charge or discharge (e.g., provide power to the mobile device).

FIG. 4B is one example of an OCP/ODP circuit 110 involving two FETS 450, 452 connected “back-to-back” where one FET is controlled to block charge current above an upper voltage threshold and the other FET is controlled to block discharge below a lower voltage threshold. In operation, both the OCP and ODP transistors 450, 452 are both on allowing current to go either direction to the battery 454. When the OCP transistor 450 is OFF and the ODP 452 transistor is ON, the charge current is blocked by the diode 456 connected in parallel to the OCP transistor, preventing charge. In the situation where OCP transistor 450 is ON and the ODP transistor 452 is OFF, the discharge current is blocked by the diode 458 connected in parallel to the ODP transistor, preventing discharge. Lastly, when both transistors 450, 452 are off, then no current will flow in or out of the battery.

The mobile device 100 may also include various conventional system 108 components, which in the case of a mobile phone or tablet may include radio communication units, WiFi communication units, a central processing unit, graphics processing unit, various forms of memory, system bus and a host of other related or distinct functional blocks depending on any given implementation. The mobile device 100 may also include a power management IC (PMIC), which may include a DC/DC converter and other components that provides power to the various system components.

The system units 108 and particularly the PMIC may be in communication with the charger MCU/IC 114 of the battery module 102. In some instances, enabling signals from the system/PMIC 108 or other system components may instruct the charger MCU 114 that the mobile device 100 is plugged in and may accept charge or indicate or initiate some other operation.

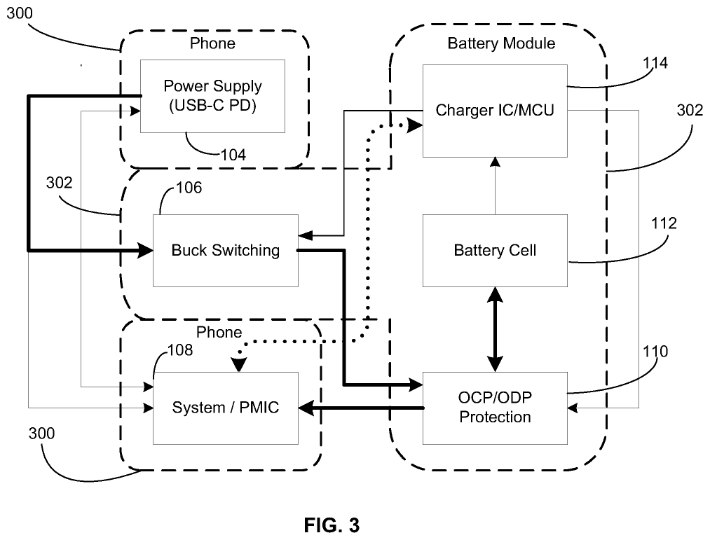

For comparison, the embodiment of FIG. 1 has the charger MCU 114 and battery 112 in the battery module 102 and other functional units are provided in the mobile device. In FIG. 2, the OCP/ODP protection unit 110 is positioned in the battery module 202 rather than the mobile device 200. In FIG. 3, the battery module 302 also includes the buck converter unit 106. In general, the OCP/ODP protection unit 110 may be embodied or included in either the mobile device 100 or the battery module 102. For example, the OCP/ODP protection unit 110 or circuit may be included on the printed circuit board of the mobile device 100, within the charger IC/MCU 114 of the battery module 102, and/or integrated into any of the modules or units discussed herein. Similarly, all or a portion of the buck switching circuit 106 may be incorporated into either mobile device 100 or the battery module 102 or integrated into any of the functional units discussed herein. In one example, the charger IC/MCU 114 may utilize existing circuits or components of the mobile device 100 as all or a portion of the buck switching circuit 106. In this example, the battery module 102 may include other portions of the buck switching circuit 106 such that the circuit is divided between the mobile device 100 and the battery module. Other modules described herein may also be shared between the mobile device 100 and the battery module 102. For example, the OCP/ODP Protection Unit 110 may also be embodied or included in both devices and/or included in other modules described.

In many cases, the buck converter 106 receives power from a power supply 104, which power is converted into a charge signal. The charge signal may be routed through the OCP/ODP 110, which may or may not let it pass depending on the voltage condition of the battery 112. The charger MCU 114 provides instructions for generating PWM signals to the buck converter 106 or directly provides PWM signals to generate the charge signal. In some instances, the charger MCU 114 may provide control signals directly to the buck converter 106 for generating the shaped charge signal, such as by providing the PWM signals to the gate or respective gates via control lines 430 and 432 of the circuit illustrated in FIG. 4A. In other instances, the charger MCU 114 may provide instructions to the computing device system controller 108 to instruct the system controller to generate the PWM signals used to control the buck converter 106. Thus, the charger MCU 114 may itself control the shaped output of the buck converter 106 for charging the battery cell 112 or may provide instructions to the system controller 108 of the computing device to control the shaped output of the buck converter. In general, any of the components of the computing device or the battery module may receive instructions from the charge MCU 114 to generate the PWM control signals to the buck converter 106 for generating the shaped charge signal.

To determine the instructions for generating the PWM control signals to the buck converter 106, the charger IC measures or receives measurements of battery parameters. The battery parameters may be voltage and/or current. In some instances, it is possible for the charging algorithm of the charger processing unit to adapt the charging signal to real-time battery conditions including voltage, which may be a discrete measurement or series of measurements, current, which may be a discrete measurement or series of measurements, and temperature among others. From the various measurements, other parameters may be determined or derived and also used by the charging algorithm. For example, impedance may be generated and the system may select a charging signal based, at least in part, on the same.

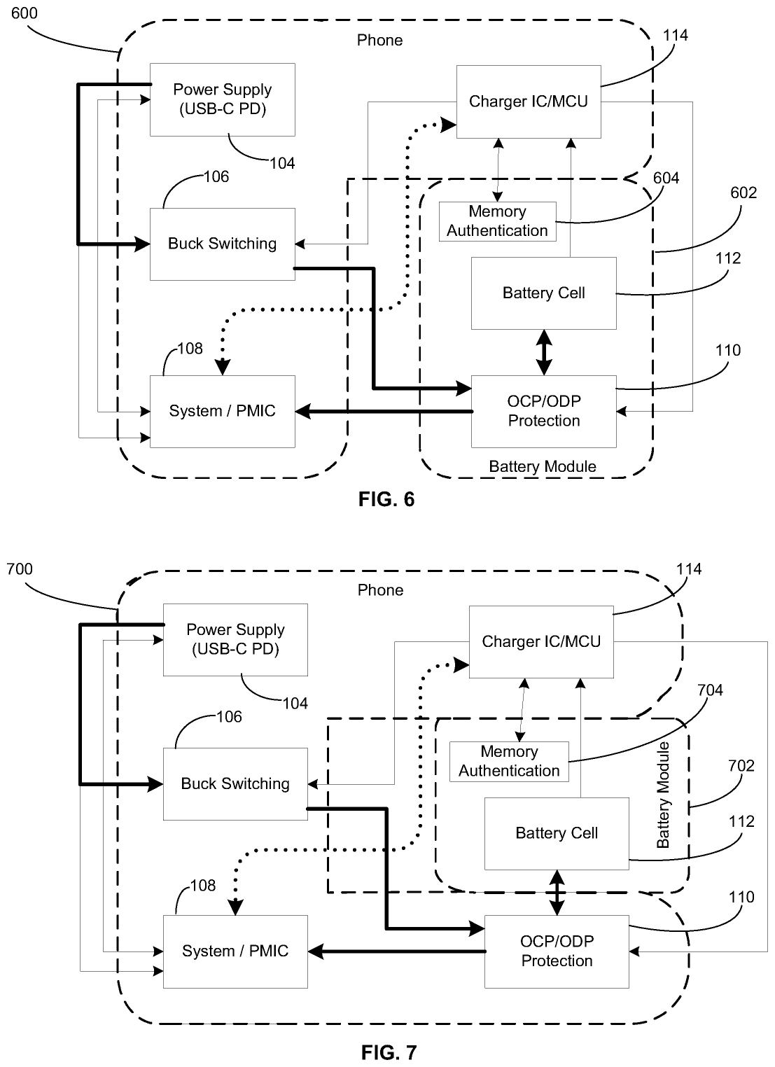

FIGS. 6 and 7 illustrate alternative smart battery arrangements 602, 702 coupled with mobile devices 600, 700 powered by a battery 112 of the respective smart battery. In FIGS. 6 and 7, the charging brains 114 (e.g., MCU) is present on the mobile device. The charging IC 114 may be a dedicated unit or may include other conventional functions as well as battery charging control instructions. The battery modules 602, 702 include a memory element 604, 704 including one or more of a battery type identifier and/or charging control information. The battery identifier includes information as to the battery type. The charging control information may include upper and lower battery voltage thresholds that may be referenced by the ODP/OCP protection unit 110, battery charging parameters, and/or a battery charging algorithm for the battery that may be uploaded to or referenced by the MCU to control charging. The memory 604, 704 may be a relatively small, e.g., 2 K, programmable read only memory or other type of memory.

In some examples, a battery charging algorithm may be unique to a specific battery type. In one example, the MCU 114 is preloaded with the battery charging algorithm and the battery type identifier stored in memory 604, 704 acts to authenticate the battery type and enable charging by way of the charging algorithm. In another example, the charging algorithm may include one or more variables that are set by way of information stored in the battery module memory 604, 704. As such, the variable elements are set with information of the particular battery type and charging may thus proceed. In another example, the mobile device 600, 700 may request an update, such as typically may occur in a software update or app update, to upload a charging algorithm based on the battery type authentication of the battery module 602, 702.

The systems illustrated in FIGS. 6 and 7 include various other functional units discussed above, with a difference being that in the embodiment illustrated in FIG. 6, the OCP/ODP protection unit 110 is positioned in the battery module 602 and in FIG. 7 it is positioned in the mobile device 700.

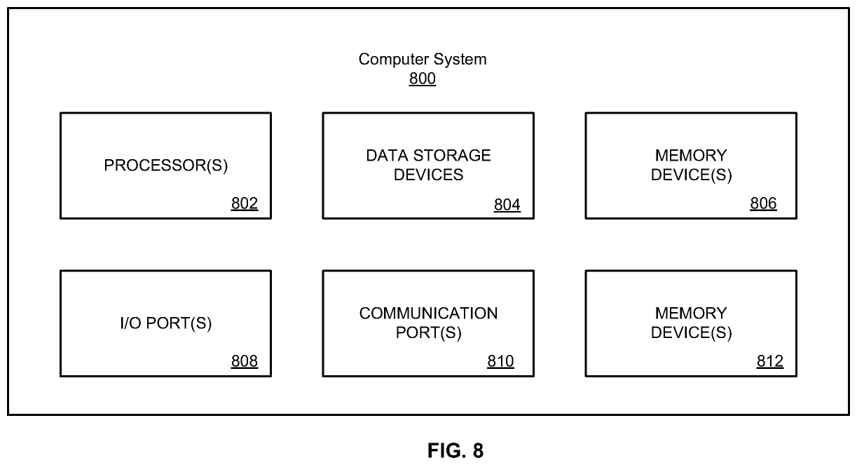

Referring to FIG. 8, the computer system 800 includes various processing components that may be involved in the battery module or the mobile device. The system 800 may be a computing system that is capable of executing a computer program product to execute a computer process. Data and program files may be input to the computer system 800, which reads the files and executes the programs therein. Some of the elements of the computer system 800 are shown in FIG. 8, including one or more hardware processors 802, one or more data storage devices 804, one or more memory devices 806, and/or one or more ports 808-812. Additionally, other elements that will be recognized by those skilled in the art may be included in the computing system 800 but are not explicitly depicted in FIG. 8 or discussed further herein. Various elements of the computer system 800 may communicate with one another by way of one or more communication buses, point-to-point communication paths, or other communication means not explicitly depicted in FIG. 8. Similarly, in various implementations, various elements disclosed in the system may or not be included in any given implementation.

The processor 802 may include, for example, a central processing unit (CPU), a microprocessor, a microcontroller, a digital signal processor (DSP), and/or one or more internal levels of cache. There may be one or more processors 802, such that the processor 802 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 804, stored on the memory device(s) 806, and/or communicated via one or more of the ports 808-812, thereby transforming the computer system 800 in FIG. 8 to a special purpose machine for implementing the operations described herein.

The one or more data storage devices 804 may include any non-volatile data storage device capable of storing data generated or employed within the computing system 800, such as computer executable instructions for performing a computer process. The one or more memory devices 806 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 804 and/or the memory devices 806, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 800 includes one or more ports, such as an input/output (I/O) port 808, a communication port 810, and a sub-systems port 812, for communicating with other computing, network, or vehicle devices. It will be appreciated that the ports 808-812 may be combined or separate and that more or fewer ports may be included in the computer system 800. The I/O port 808 may be connected to an I/O device, or other device, by which information is input to or output from the computing system 800. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 800 via the I/O port 808. In some examples, such inputs may be distinct from the various system and method discussed with regard to the preceding figures. Similarly, the output devices may convert electrical signals received from computing system 800 via the I/O port 808 into signals that may be sensed or used by the various methods and system discussed herein. The input device may be an alphanumeric input device, including alphanumeric and other keys for communicating information and/or command selections to the processor 802 via the I/O port 808.

The environment transducer devices convert one form of energy or signal into another for input into or output from the computing system 800 via the I/O port 808. For example, an electrical signal generated within the computing system 800 may be converted to another type of signal, and/or vice-versa. In one implementation, the environment transducer devices sense characteristics or aspects of an environment local to or remote from the computing device 800, such as battery voltage, open circuit battery voltage, charge current, battery temperature, light, sound, temperature, pressure, magnetic field, electric field, chemical properties, and/or the like.

In one implementation, a communication port 810 may be connected to a network by way of which the computer system 800 may receive network data useful in executing the methods and systems set out herein as well as transmitting information and network configuration changes determined thereby. For example, charging protocols may be updated, battery measurement or calculation data shared with external system, and the like. The communication port 810 connects the computer system 800 to one or more communication interface devices configured to transmit and/or receive information between the computing system 800 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 810 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 800 may include a sub-systems port 812 for communicating with one or more systems related to a device being charged according to the methods and system described herein to control an operation of the same and/or exchange information between the computer system 800 and one or more sub-systems of the device. Examples of such sub-systems of a vehicle, include, without limitation, motor controllers and systems, battery control systems, and others.

The system set forth in FIG. 8 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A system comprising:
a computing device; and
a battery module in communication with the computing device and providing a power signal to the computing device, the battery module comprising:
a battery; and
a processing configuration to charge the battery consistent with a battery charging control instructions, wherein the battery charging control instructions cause a switching circuit of the computing device comprising at least one switch and at least one inductor operably coupled with the at least one switch to generate a charge signal for charging the battery, wherein the generated charge signal includes at least one harmonically tuned aspect.

2. The system of claim 1 wherein the processing configuration comprises a controller configured to execute the battery charging control instructions.

3. The system of claim 2 wherein the controller is a microcontroller.

4. The system of claim 1 wherein the processing configuration comprises a memory storing information for the battery charging control instructions to generate the charge signal for the battery.

5. The system of claim 1 wherein the battery module further comprises an over-charge/over-discharge protection circuit comprising a first switching device and a second switching device connected in series to control a charge signal to the battery.

6. The system of claim 5 wherein the first switching device and the second switching device further control a discharge signal from the battery.

7. The system of claim 5 wherein at least a portion of the over-charge/over-discharge protection circuit is included in a computing device being powered by the battery.

8. The system of claim 1 wherein at least a portion of the switching circuit is included in the battery housing.

9. The system of claim 1 wherein the battery provides power to a computing device and at least a portion of the switching circuit is included in a computing device being powered by the battery.

10. The system of claim 1 wherein the at least one harmonically tuned aspect of the charge signal comprises a harmonic associated with an impedance value of a computing device powered by the battery.

11. The system of claim 1 wherein the at least one harmonically tuned aspect of the charge signal comprises a non-linear leading edge.

12. The system of claim 11 wherein the non-linear leading edge comprises one or more linear approximations of a portion of a sinusoid.

13. The system of claim 11 wherein the charge signal further comprises a body portion comprising a first non-sinusoidal charge current following the non-linear leading edge.

14. The system of claim 13 wherein the charge signal further comprises a rest portion comprising a second non-sinusoidal charge current following the body portion, the second non-sinusoidal charge current less than the first non-sinusoidal charge current.

15. A method of charging an electrochemical device comprising:
determining, by a processing device of a battery module, a charge signal to charge a battery of the battery module, the battery module in communication with a computing device separate from the battery module and providing, by the battery, a power signal to power the computing device; and
transmitting battery charging control instructions to a switching circuit of a computing device, the switching circuit comprising at least one switch and at least one inductor operably coupled with the at least one switch, the battery charging control instructions causing the switching circuit to generate the charge signal to charge the battery of the battery module, wherein the generated charge signal includes at least one harmonically tuned aspect.

16. The method of claim 15 further comprising:
controlling a charge signal to the battery by an over-charge/over-discharge protection circuit comprising a first switching device and a second switching device connected in series.

17. The method of claim 16 wherein the first switching device and the second switching device further control a discharge signal from the battery.

18. The method of claim 16 wherein at least a portion of the over-charge/over-discharge protection circuit is included in the computing device being powered by the battery.

19. The method of claim 15 wherein at least a portion of the switching circuit is included in the battery module.

20. A battery module comprising:
a battery housing comprising a battery and a processing configuration to charge the battery consistent with battery charging control instructions by generating a charge signal through control of a switching circuit comprising at least one switch and at least one inductor operably coupled with the at least one switch, wherein the generated charge signal includes at least one harmonically tuned aspect.
